(19) United States
(12) Patent Application Publication
(10) Pub. No.: US 2026/0348012 A1
(43) Pub. Date: Nov. 5, 2026

(54) VAPOR DELIVERY SYSTEM, SEMICONDUCTOR PROCESSING SYSTEM, AND METHOD FOR PERFORMING DEPOSITION PROCESS

(71) Applicant: ASM IP Holding B.V., Almere (NL)

(72) Inventors: Bradley Wayne Evans, Apache Junction, AZ (US); Krishnaswamy Mahadevan, Tempe, AZ (US)

(21) Appl. No.: 19/658,833

(22) Filed: Apr. 27, 2026

Related U.S. Application Data
(60) Provisional application No. 63/797,891, filed on Apr. 30, 2025.

(51) Int. Cl. C23C 16/455; C23C 16/44; C23C 16/448

(52) U.S. Cl. CPC C23C 16/45561; C23C 16/4408; C23C 16/4481; C23C 16/45557

(57) ABSTRACT

A vapor delivery system is provided, which includes a container having a space for storing a solid phase precursor, an evaporator in fluid communication with the container and vaporizing the solid phase precursor into a vapor phase precursor, a reservoir in fluid communication with the evaporator and configured to store the vapor phase precursor, a carrier gas source coupled to the reservoir and configured to provide a carrier gas into the reservoir to form a gas mixture in the reservoir from the vapor phase precursor and the carrier gas, a flow controller in fluid communication with the reservoir and connected downstream of the reservoir, and a reaction chamber in fluid communication with the flow controller.

### CROSS-REFERENCE TO RELATED APPLICATIONS

This application is a nonprovisional of, and claims priority to and the benefit of, U.S. Provisional Patent Application No. 63/797,891, filed Apr. 30, 2025 and entitled “VAPOR DELIVERY SYSTEM, SEMICONDUCTOR PROCESSING SYSTEM, AND METHOD FOR PERFORMING DEPOSITION PROCESS,” which is hereby incorporated by reference herein.

### FIELD

The present disclosure relates to a vapor delivery system, a semiconductor processing system, and a method for performing a deposition process.

### BACKGROUND

During the manufacture of electronic devices, thin films or layers are often deposited onto a surface of a substrate using one or more precursors. In some cases, the precursor can be a liquid at normal temperature and pressure (NTP) and can be vaporized for use in gas-phase reactions. The precursor can be delivered to a reaction chamber using a liquid delivery system.

However, such a configuration consumes lots of energy because the entire liquid mass must be maintained at elevated temperature. Furthermore, such a system cannot accommodate precursors that are solids at room temperature or that decompose before melting. Moreover, concentration control is open-loop, which relies only on upstream pressure or mass flow feedback, so transient changes in vapor pressure or carrier flow can translate into nonuniformities of film growth.

### BRIEF SUMMARY

A vapor delivery system is provided in some embodiments, which includes a container having a space for storing a solid phase precursor, an evaporator in fluid communication with the container and vaporizing the solid phase precursor into a vapor phase precursor, a reservoir in fluid communication with the evaporator and configured to store the vapor phase precursor, a carrier gas source coupled to the reservoir and configured to provide a carrier gas into the reservoir to form a gas mixture in the reservoir from the vapor phase precursor and the carrier gas, a flow controller in fluid communication with the reservoir and connected downstream of the reservoir, and a reaction chamber in fluid communication with the flow controller.

In some embodiments, the vapor delivery system further includes a solid flow sensor coupled downstream of the container.

In some embodiments, the vapor delivery system further includes a control unit coupled to the carrier gas source, wherein the control unit is configured to control flow rate of the carrier gas.

In some embodiments, the vapor delivery system further includes a concentration sensor coupled to the control unit and the flow controller, wherein the concentration sensor is configured to detect the concentration of the gas mixture to provide a concentration value, and the control unit controls flow rate of the gas mixture based on the concentration value.

In some embodiments, the concentration sensor is disposed downstream of the reservoir, and upstream of the flow controller.

In some embodiments, the vapor delivery system further includes a purge gas source connected to the container and configured to provide a purge gas into the container.

A semiconductor processing system is provided in some embodiments, which includes a vapor delivery system, a reaction chamber in fluid communication with the vapor delivery system, and a vacuum assembly in fluid communication with the reaction chamber, the vacuum assembly configured to remove excess vapor phase precursor from the reaction chamber. The vapor delivery system includes a container having a space for storing a solid phase precursor, an evaporator in fluid communication with the container and vaporizing the solid phase precursor into a vapor phase precursor, a reservoir in fluid communication with the evaporator and configured to store the vapor phase precursor, a carrier gas source coupled to the reservoir and configured to provide a carrier gas into the reservoir to form a gas mixture in the reservoir from the vapor phase precursor and the carrier gas, and a flow controller in fluid communication with the reservoir and connected downstream of the reservoir.

In some embodiments, the semiconductor processing system further includes a solid flow sensor coupled downstream of the container.

In some embodiments, the semiconductor processing system further includes a pressure controller coupled to the carrier gas source, wherein the pressure controller is configured to control flow rate of the carrier gas.

In some embodiments, the semiconductor processing system further includes a control unit coupled to the pressure controller and the flow controller.

In some embodiments, the semiconductor processing system further includes a concentration sensor coupled to the control unit and the flow controller, wherein the concentration sensor is configured to detect the concentration of the gas mixture to provide a concentration value, and the control unit controls flow rate of the gas mixture based on the concentration value.

In some embodiments, the concentration sensor is disposed downstream of the reservoir, and upstream of the flow controller.

In some embodiments, the semiconductor processing system further includes a purge gas source connected to the container and configured to provide a purge gas into the container.

In some embodiments, the vacuum assembly is disposed downstream of the reaction chamber.

A method for performing a deposition process is provided in some embodiments, which includes heating a solid phase precursor in an evaporator to form a vapor phase precursor, mixing the vapor phase precursor and a carrier gas in a reservoir to form a gas mixture, measuring a concentration of the vapor phase precursor in the gas mixture by a concentration sensor to get a result, adjusting the concentration of the vapor phase precursor based on the result, transferring the gas mixture into a reaction chamber, and performing the deposition process in the reaction chamber by using the gas mixture as a reactive precursor.

In some embodiments, the method further includes measuring grain size of the solid phase precursor before the solid phase precursor is provided into the evaporator.

In some embodiments, adjusting the concentration of the vapor phase precursor includes adjusting a flow rate of the carrier gas by a first control unit disposed upstream of the reservoir.

In some embodiments, adjusting the concentration of the vapor phase precursor includes adjusting a flow rate of the gas mixture by a second control unit disposed downstream of the reservoir.

In some embodiments, the method further includes feeding the solid phase precursor and a purge gas into a container disposed upstream of the evaporator.

In some embodiments, the solid phase precursor is in prill form.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic view of a vapor delivery system, in accordance with some embodiments.

FIG. 2 is a schematic view of a process flow diagram showing a method for delivering vapor for performing a deposition process, in accordance with some embodiments.

FIG. 3 is a schematic view of a semiconductor processing system, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Unless defined otherwise, all technical and scientific terms used herein have the same meaning as commonly understood by one of ordinary skill in the art to which this disclosure belongs. It should be appreciated that each term, which is defined in a commonly used dictionary, should be interpreted as having a meaning conforming to the relative skills and the background or the context of the present disclosure, and should not be interpreted in an idealized or overly formal manner unless defined otherwise.

Use of ordinal terms such as “first”, “second”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

It will be understood that when an element is referred to as being “connected to” or “coupled to” another element, it may be directly connected to or coupled to the other element, or one or more intervening elements may be present.

In some cases, such as in the context of deposition of material, the term “precursor” can refer to a compound that participates in the chemical reaction that produces another compound, and particularly to a compound that constitutes a film matrix or a main skeleton of a film.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In accordance with aspects of the disclosure, any defined meanings of terms do not necessarily exclude ordinary and customary meanings of the terms.

The present disclosure provides a vapor delivery system that feeds solid phase precursor into an evaporator for generating vapor phase precursor. Such a vapor phase precursor is then delivered into a reaction chamber to perform a deposition process. Such a system minimizes energy consumption and precursor waste when compared with systems using liquid precursor.

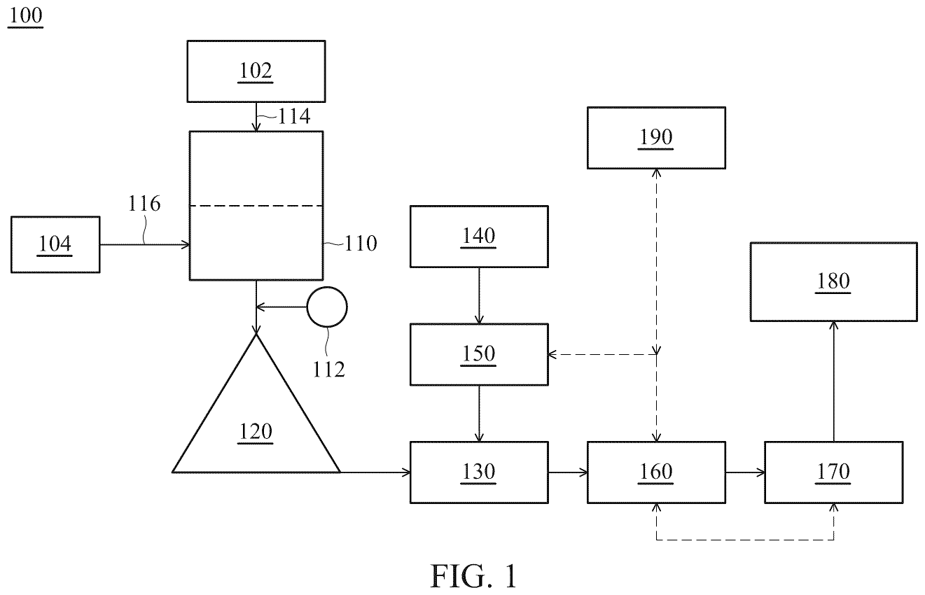

FIG. 1 is a schematic view of a vapor delivery system 100, in accordance with some embodiments. For ease of illustration, the main functional blocks are arranged sequentially along the process flow path, although other spatial layouts may be adopted in practice. As shown in FIG. 1, the vapor delivery system 100 mainly includes a container 110, an evaporator 120, a reservoir 130, a carrier gas source 140, a pressure controller 150, a concentration sensor 160, a flow controller 170, a reaction chamber 180, and a control unit 190.

In some embodiments, solid phase precursor 102 is fed into the container 110 through a first inlet 114, and purge gas 104 is simultaneously fed into the container through a second inlet 116 from a purge gas source connected to the container 110. The first inlet 114 and the second inlet 116 are different. Such physical separation prevents cross-contamination between the precursor feed line and the purge gas line, thereby reducing maintenance frequency. The provision of two separate inlets also allows for independent and controlled delivery of different process gases, thereby improving the operational flexibility and process efficiency. In some embodiments, the container 110 has a space for storing the solid phase precursor 102.

In some embodiments, the container 110 may be fabricated from corrosion-resistant alloys to withstand chemistries or elevated storage temperatures specified for the precursor. For example, the container 110 may be fabricated from 304 or 316 stainless steel for moderately reactive chemistries, from Hastelloy-C or other nickel-based alloys for highly corrosive halide-containing precursors, or from components internally lined with fluoropolymer coatings (e.g., PTFE or PFA) to provide an inert barrier layer. Selection of the appropriate material or liner is governed by the corrosivity, operating temperature, and impurity-sensitivity requirements of the specific precursor chemistry being employed, in accordance with some embodiments.

In some embodiments, the purge gas 104 is used for maintaining a slight over-pressure to prevent ambient moisture or oxygen from entering the container 110 during refills and operation. In some embodiments, the purge gas 104 also establishes a continuous gas flow vector directed toward the evaporator 120 during each dosing event to prevent the solid phase precursor 102 particles from agglomerating, thereby reducing the risk of clogging and ensuring consistent, one-directional delivery of prill material into the evaporator 120.

In some embodiments, the solid phase precursor 102 is in prill form. Because the solid phase precursor 102 remains at or near ambient temperature while stored in the container 110, overall power consumption is reduced when compared with systems that maintain the entire precursor inventory at elevated temperature. Furthermore, no heating part is required for the container 110. As a result, the size of the entire vapor delivery system 100 may also be reduced to achieve miniaturization.

In some embodiments, a solid flow sensor 112 is coupled downstream of the container 110, such as in the feed path between the container 110 and the evaporator 120. The solid flow sensor 112 is used to measure the mass-flow rate of the solid phase precursor 102 entering the evaporator 120 before the solid phase precursor 102 is introduced into the evaporator 120, such as measuring the grain size of the solid phase precursor 102. Accurate mass flow feedback enables closed loop control that compensates feed instabilities. In some embodiments, the solid flow sensor 112 is an optical sensor. In some embodiments, the solid flow sensor 112 includes at least one of a laser sensor and a Doppler sensor to compensate for variations in pellet size and intermittent feed. Solid flow sensor 112 stabilizes evaporator pressure and minimizes precursor waste.

The evaporator 120 is in fluid communication with the container 110, and the solid phase precursor 102 is then fed from the container 110 to the evaporator 120. In some embodiments, the evaporator 120 has a localized hot zone that heats or vaporizes the solid phase precursor 102 into a vapor phase precursor. The hot zone may be a localized hot region formed by electrical heaters, heat-transfer fluids, or other thermal sources that raise the temperature of the solid phase precursor above its sublimation or evaporation threshold. Because only the material within the evaporator is heated, energy consumption is reduced, and the rest of the delivery line remains near room temperature. The evaporator 120 may include temperature sensors, flow baffles, or internal surfaces optimized for uniform heating, thereby promoting stable evaporation rates and minimizing precursor decomposition. The temperature of the hot zone in the evaporator 120 may be chosen based on different precursors.

Since the particle size (grain size) of the solid phase precursor 102 may be unstable, the flow rate of the resulting vapor phase precursor may also be unstable. Hence, the reservoir 130 is in fluid communication with the evaporator 120 and configured to store the vapor phase precursor. The reservoir 130 has a size greater than the evaporator 120, and serves as a buffer volume. For example, the reservoir 130 temporarily stores the vapor phase precursor, and the internal volume of the reservoir 130 is sized to damp pressure spikes caused by variable grain size of the solid phase precursor 102. By smoothing out pressure fluctuations, the flow rate of the gas mixture is stabilized.

In some embodiments, the carrier gas source 140 is coupled upstream of the reservoir 130 and configured to provide a carrier gas into the reservoir 130, and then the vapor phase precursor and the carrier gas are mixed in the reservoir 130 to form a gas mixture. For example, the carrier gas source 140 supplies a regulated flow of inert gas (typically nitrogen, argon, or helium) used to dilute the vapor phase precursor to the target molar concentration. Afterwards, the flow rate of the carrier gas from the carrier gas source 140 is controlled by the pressure controller 150 disposed between the carrier gas source 140 and the reservoir 130, and the pressure controller 150 is controlled by the control unit 190 coupled to the carrier gas source 140 and disposed upstream of the reservoir 130, so a gas mixture is formed in the reservoir 130 by mixing the carrier gas and the vapor phase precursor. The pressure controller 150 enables dilution of the vapor phase precursor in the reservoir 130 by adding carrier gas, so the concentration of the vapor phase precursor in the reservoir 130 may be controlled to a desired value. In some embodiments, the control unit 190 may include modules, such as a software or hardware component, e.g., FPGA or ASIC, which perform certain tasks.

In some embodiments, the concentration sensor 160 is coupled to the control unit 190 and configured to detect or measure the concentration of the gas mixture exiting the reservoir 130 to get a result, such as a concentration value of the gas mixture. Afterwards, the result is provided to the control unit 190, and the concentration of the vapor phase precursor in the gas mixture is adjusted by the control unit 190 based on the result. For example, the control unit 190 receives the concentration value of the gas mixture, and controls flow rate of the carrier gas by the pressure controller 150 based on the concentration value for adjusting the concentration of the vapor phase precursor in the gas mixture. In some embodiments, the concentration sensor 160 includes an in-line infrared absorption cell, laser spectroscopy, or equivalent optical techniques.

In some embodiments, the flow controller 170 is in fluid communication with the reservoir 130, connected downstream of the reservoir 130, and coupled to the concentration sensor 160 and the control unit 190. In some embodiments, the concentration sensor 160 is disposed downstream of the reservoir 130, and upstream of the flow controller 170. In some embodiments, the flow controller 170 may be a high-precision mass-flow controller (MFC) which meters the combined carrier gas/vapor phase precursor mixture delivered to the reaction chamber 180, and the flow controller 170 is dynamically adjusted by the control unit 190, and the adjustment is based on the concentration value of the gas mixture detected by the concentration sensor 160 to achieve the desired flow rate, thereby achieving desired concentration of the vapor phase precursor.

Since the grain size of the solid phase precursor 102 varies and the evaporation efficiency changes over time, such a closed-loop architecture continuously adjusts the carrier gas flow to maintain a more stable precursor concentration, compared to an open-loop scheme that relies solely on precalibrated MFC settings. Accordingly, the closed-loop configuration provides more accurate dosing and improved process repeatability, in accordance with some embodiments.

In some embodiments, the reaction chamber 180 is in fluid communication with the flow controller 170. The reaction chamber 180 is disposed downstream of the flow controller 170, and the gas mixture is transferred into the reaction chamber 180 with controlled concentration and flow rate for different reactions in the reaction chamber 180. The reaction chamber 180 may be used for performing vapor phase processes by using the gas mixture as a reactive precursor, such as deposition processes. Examples of the processes include atomic layer deposition (ALD), chemical vapor deposition (CVD), plasma-enhanced chemical vapor deposition (PECVD), plasma-enhanced atomic layer deposition (PEALD), atomic layer etch (ALEt) processes, chemical vapor etch (CVE) processes, and plasma based dry-etch processes, for example. Because the upstream delivery architecture isolates concentration and flow variations, the reaction chamber 180 receives a uniform, precisely metered precursor dose, enabling repeatable thin film growth and increasing the yield of device fabrication. Moreover, the stabilized feed reduces defect density associated with precursor starvation or oversupply, which is critical for advanced semiconductor nodes.

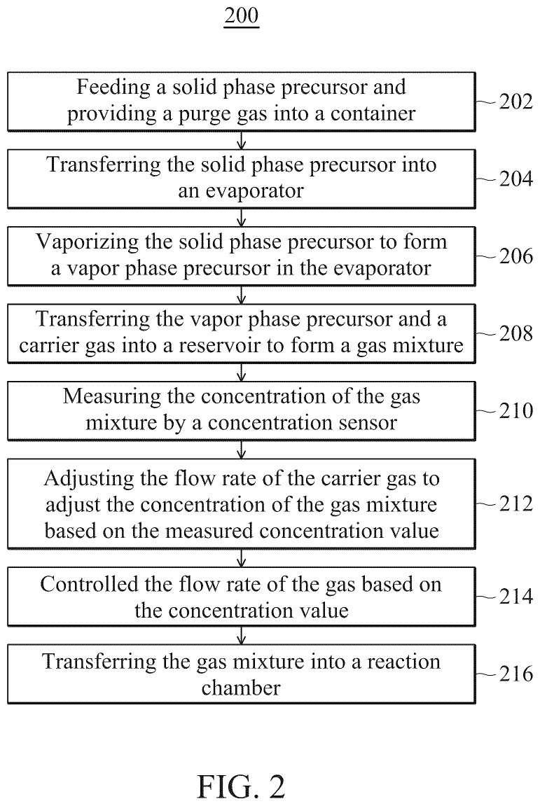

FIG. 2 is a schematic view of a process flow diagram showing a method 200 for delivering vapor for performing a deposition process, in accordance with some embodiments. For clarity, the steps are described in a logical order; however, certain steps may be performed in parallel or in a different sequence as dictated by process integration requirements. At step 202, the solid phase precursor 102 is fed into the container 110 through the first inlet 114, and a purge gas is provided into the container 110 through the second inlet 116 different from the first inlet 114. At step 204, the solid phase precursor 102 is transferred from the container 110 into the evaporator 120, and the flow rate of the solid phase precursor 102 is measured by the solid flow sensor 112 coupled downstream of the container 110. At step 206, the solid phase precursor 102 is vaporized to form a vapor phase precursor in the evaporator 120. At step 208, the vapor phase precursor and a carrier gas are transferred into the reservoir 130 to form the gas mixture by mixing the vapor phase precursor and the carrier gas, wherein the vapor phase precursor is transferred from the evaporator 120, and the carrier gas is provided from the carrier gas source 140 and controlled by the control unit 190.

At step 210, the concentration of the gas mixture is measured by the concentration sensor 160 disposed downstream of the reservoir 130. At step 212, the concentration sensor 160 provides the result of measured concentration value to the control unit 190, and then the control unit 190 adjusts the flow rate of the carrier gas from the carrier gas source 140 based on the result, thereby adjusting the concentration of the gas mixture in the reservoir 130. At step 214, the flow rate of the gas mixture is controlled by the flow controller 170 connected downstream of the concentration sensor 160 based on the concentration value measured by the concentration sensor 160. At step 216, the gas mixture is transferred into the reaction chamber 180 for performing subsequent processes in the reaction chamber 180, such as a deposition process. Through this closed-loop controlling vapor delivery system 100, both concentration and volumetric flow are regulated in real time, ensuring process repeatability across multiple production lots.

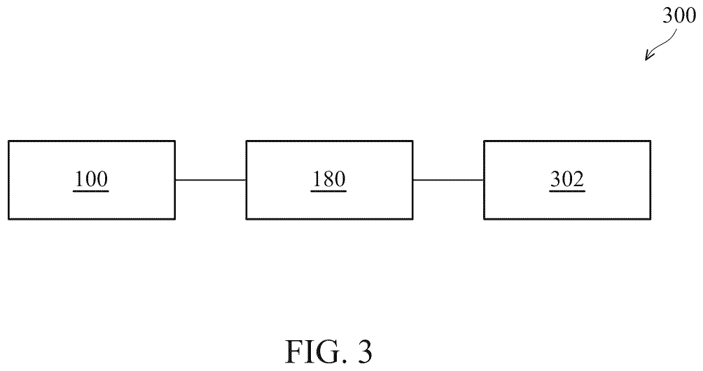

In some embodiments, the vapor delivery system 100 is applicable for a semiconductor processing system. For example, FIG. 3 is a schematic view of a semiconductor processing system 300, in accordance with some embodiments. As shown in FIG. 3, the semiconductor processing system 300 includes the vapor delivery system 100, the reaction chamber 180, and a vacuum assembly 302. In some embodiments, the vacuum assembly 302 is in fluid communication with the reaction chamber 180 and disposed downstream of the reaction chamber 180, and the vacuum assembly 302 is configured to remove excess vapor phase precursor from the reaction chamber 180. This arrangement maintains chamber purity, stabilizes process pressure, and improves film uniformity and repeatability. Therefore, overall process efficiency and yield may be increased by connecting the vacuum assembly 302 to the reaction chamber 180.

In summary, a vapor delivery system is provided in some embodiments, which includes a container comprising a space for storing a solid phase precursor, an evaporator in fluid communication with the container and vaporizing the solid phase precursor into a vapor phase precursor, a reservoir in fluid communication with the evaporator and configured to store the vapor phase precursor, a carrier gas source coupled to the reservoir and configured to provide a carrier gas into the reservoir to form a gas mixture in the reservoir from the vapor phase precursor and the carrier gas, a flow controller in fluid communication with the reservoir and connected downstream of the reservoir, and a reaction chamber in fluid communication with the flow controller.

Such a vapor delivery system converts a solid phase precursor into a vapor phase precursor in a localized hot spot evaporator, wherein only the material in transit is heated. Therefore, total energy consumption is lowered to reduce cost, and size of the entire system is also reduced.

Although embodiments of the present disclosure and their advantages have been described in detail, it should be understood that various changes, substitutions, and alterations can be made herein without departing from the spirit and scope of the disclosure as defined by the appended claims. Moreover, the scope of the present application is not intended to be limited to the particular embodiments of the process, machine, manufacture, and composition of matter, means, methods, and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, and compositions of matter, means, methods, or steps. In addition, each claim constitutes a separate embodiment, and the combination of various claims and embodiments are within the scope of the disclosure.

What is claimed is:

1. A vapor delivery system, comprising:
a container comprising a space for storing a solid phase precursor;
an evaporator in fluid communication with the container, wherein the evaporator vaporizes the solid phase precursor into a vapor phase precursor;
a reservoir in fluid communication with the evaporator and configured to store the vapor phase precursor;
a carrier gas source coupled to the reservoir and configured to provide a carrier gas into the reservoir to form a gas mixture in the reservoir from the vapor phase precursor and the carrier gas;
a flow controller in fluid communication with the reservoir and connected downstream of the reservoir; and
a reaction chamber in fluid communication with the flow controller.

2. The vapor delivery system of claim 1, further comprising a solid flow sensor coupled downstream of the container.

3. The vapor delivery system of claim 1, further comprising a control unit coupled to the carrier gas source, wherein the control unit is configured to control flow rate of the carrier gas.

4. The vapor delivery system of claim 3, further comprising a concentration sensor coupled to the control unit and the flow controller, wherein the concentration sensor is configured to detect a concentration of the gas mixture to provide a concentration value, and the control unit controls flow rate of the gas mixture based on the concentration value.

5. The vapor delivery system of claim 4, wherein the concentration sensor is disposed downstream of the reservoir, and upstream of the flow controller.

6. The vapor delivery system of claim 1, further comprising a purge gas source connected to the container and configured to provide a purge gas into the container.

7. A semiconductor processing system, comprising:
a vapor delivery system, comprising:
a container comprising a space for storing a solid phase precursor;
an evaporator in fluid communication with the container, wherein the evaporator vaporizes the solid phase precursor into a vapor phase precursor;
a reservoir in fluid communication with the evaporator and configured to store the vapor phase precursor;
a carrier gas source coupled to the reservoir and configured to provide a carrier gas into the reservoir to form a gas mixture in the reservoir from the vapor phase precursor and the carrier gas;
a flow controller in fluid communication with the reservoir and connected downstream of the reservoir;
a reaction chamber in fluid communication with the vapor delivery system; and
a vacuum assembly in fluid communication with the reaction chamber, the vacuum assembly configured to remove excess vapor phase precursor from the reaction chamber.

8. The semiconductor processing system of claim 7, further comprising a solid flow sensor coupled downstream of the container.

9. The semiconductor processing system of claim 7, further comprising a pressure controller coupled to the carrier gas source, wherein the pressure controller is configured to control flow rate of the carrier gas.

10. The semiconductor processing system of claim 9, further comprising a control unit coupled to the pressure controller and the flow controller.

11. The semiconductor processing system of claim 10, further comprising a concentration sensor coupled to the control unit and the flow controller, wherein the concentration sensor is configured to detect a concentration of the gas mixture to provide a concentration value, and the control unit controls flow rate of the gas mixture based on the concentration value.

12. The semiconductor processing system of claim 11, wherein the concentration sensor is disposed downstream of the reservoir, and upstream of the flow controller.

13. The semiconductor processing system of claim 7, further comprising a purge gas source connected to the container and configured to provide a purge gas into the container.

14. The semiconductor processing system of claim 7, wherein the vacuum assembly is disposed downstream of the reaction chamber.

15. A method for performing a deposition process, comprising:
heating a solid phase precursor in an evaporator to form a vapor phase precursor;
mixing the vapor phase precursor and a carrier gas in a reservoir to form a gas mixture;
measuring a concentration of the vapor phase precursor in the gas mixture by a concentration sensor to get a result;
adjusting the concentration of the vapor phase precursor based on the result;
transferring the gas mixture into a reaction chamber; and
performing the deposition process in the reaction chamber by using the gas mixture as a reactive precursor.

16. The method of claim 15, further comprising measuring grain size of the solid phase precursor before the solid phase precursor is provided into the evaporator.

17. The method of claim 15, wherein adjusting the concentration of the vapor phase precursor comprises adjusting a flow rate of the carrier gas by a first control unit disposed upstream of the reservoir.

18. The method of claim 15, wherein adjusting the concentration of the vapor phase precursor comprises adjusting a flow rate of the gas mixture by a second control unit disposed downstream of the reservoir.

19. The method of claim 15, further comprising feeding the solid phase precursor and a purge gas into a container disposed upstream of the evaporator.

20. The method of claim 15, wherein the solid phase precursor is in prill form.
